(19) United States
(12) Patent Application Publication
(10) Pub. No.: US 2003/0080376 A1
(43) Pub. Date: May 1, 2003

(54) Transistor device

(75) Inventors: Philip Rutter, Stockport (GB); Steven T. Peake, Warrington (GB)

Correspondence Address: Corporate Patent Counsel, U.S. Philips Corporation, 580 White Plains Road, Tarrytown, NY, 10591, US

(73) Assignee: KONINKLIJKE PHILIPS ELECTRONICS N.V.

(21) Appl. No.: 10/264,895

(22) Filed: Oct. 4, 2002

(30) Foreign Application Priority Data
Oct. 26, 2001 (GB) 0125710.4

(51) Int. Cl. H01L 29/76

(52) U.S. Cl. 257/328

(57) ABSTRACT

A transistor has a plurality of active zones, (22, 24) separated by separation regions (10). The zones include wide (22) and narrow (24) zones, and the wide zones are formed to be less susceptible to turning on a parasitic bipolar transistor, for example by omitting a source region (8) from the wide zones (22), so causing avalanche current to flow preferentially in the wide zones (22) which have a lesser susceptibility to turning on the parasitic bipolar transistor.

The invention relates to a transistor and its operation, and in particular to a gated transistor such as a field effect transistor (FET) or an insulated gate bipolar transistor (IGBT) divided into a plurality of lateral zones.

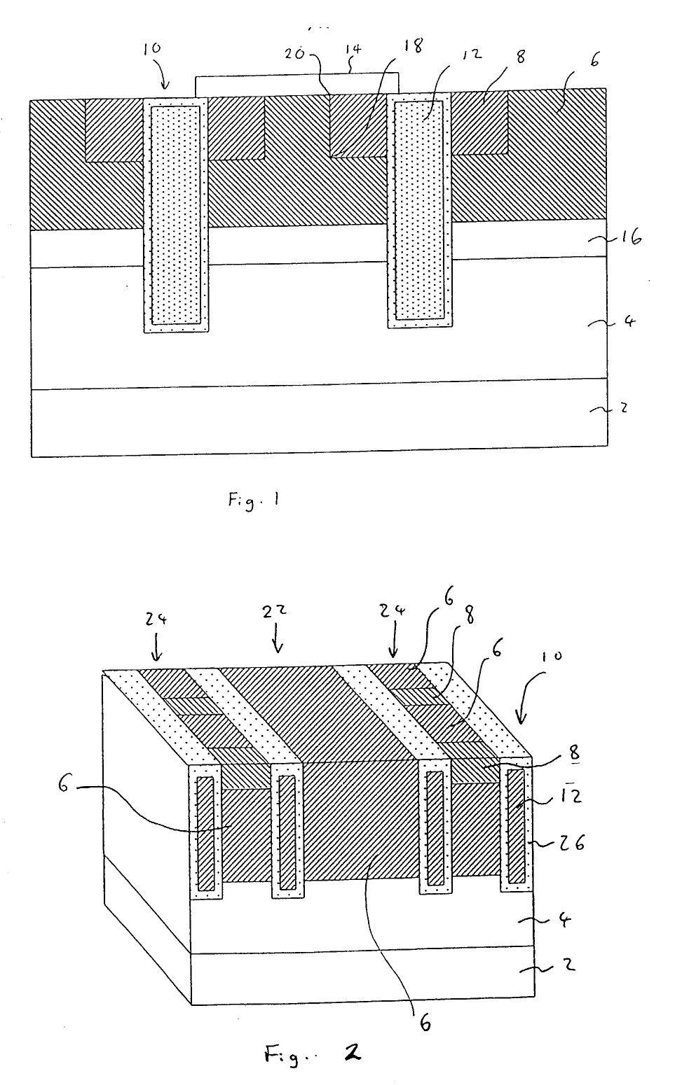

One example of a transistor structure is the trench-gated FET. These are particularly suitable for use in some applications of power MOSFETs. In a typical example, illustrated in FIG. 1, of a vertical trench MOSFET an epilayer 4 on a substrate 2 functions as the drain layer of the FET, and a body layer 6 and a source layer 8 are provided over the drain layer 4. A plurality of insulated trenches 10 containing gates 12 extend through the source 8 and body 6 layers into the drain layer. A source contact 14 contacts the source region 8, and also the body region 6 as will be explained below.

FET structures can suffer from a number of problems, one of which is avalanche breakdown when too high a voltage is applied between source and drain. A good approach to dealing with breakdown is described in United States patent specification U.S. Pat. No. 4,754,310 assigned to US Philips Corp. This basic patent describes the use of a device having charge-balanced p and n type regions which are depleted when the device is switched off so that they can support a higher voltage across them without breaking down than would otherwise be the case. Semiconductor devices of this beneficial general type have come to be known as “RESURF” (Reduced Surface Field) devices.

The RESURF principle may also be applied to trench MOSFETs without using interleaved layers, for example as disclosed in WO01/08226A1 to Philips. This document is incorporated herein by reference in its entirety. The trenches are closely spaced and arranged adjacent to an intermediate region that is sufficiently lightly doped that an intermediate region 16, known as the drift region, can be depleted between the neighbouring trenches at a voltage less than the breakdown voltage.

A further problem in FETs is the existence of parasitic bipolar transistors, formed from the source, body and drain regions. Referring to FIG. 1, the source 8 and body 6 form the emitter and base of the parasitic transistor. By shorting the source 8 and body 6 together, for example by connecting both to the source contact 14 as shown, the emitter and base of the parasitic transistor are shorted together which suppresses the parasitic bipolar transistor.

However, under high current operation sufficient current may flow through the body region 6 past the source region to the metallisation that a voltage is dropped in the body region between the metallisation/body boundary 20 and the source/body boundary 18. If this voltage is high enough, the voltage is sufficient to forward bias the parasitic transistor which then drives an increased current, further increasing the forward bias and so on to form a hot spot.

Even if failure does not occur, the voltage needed to trigger the parasitic in subsequent events will be reduced by the high temperatures, leading to a more rapid turn on of the parasitic transistor. After a number of events the device may fail as the hot spot gets hotter and hotter in each event.

A particular high current condition that may occur is avalanche breakdown. It is desirable that the transistor can cope with the avalanche current without switching on the parasitic bipolar transistor, forming a hot spot and possibly destroying the device. The ability to cope with avalanche breakdown without damage is known as “ruggedness”.

Conventional designs generally attempt to achieve a high level of uniformity across a FET to uniformly spread the avalanche current across the structure. For example, in devices having a plurality of cells, conventional design aims to spread the avalanche current evenly between the cells to avoid excessive current in one cell causing triggering of the parasitic transistor in that cell.

An alternative prior approach is to reduce the gain of the transistor and the base resistance of the parasitic transistor by increasing the p-type doping underneath the source with an additional implant, i.e. a further implant additional to a p body threshold implant.

However, the prior approaches does not fully deal with the problem and there remains a need for high ruggedness devices.

Further, parasitic bipolar transistors are not only a problem in conventional FET structures, but may also occur in other types of device, for example, in insulated gate bipolar structures. It would be useful to reduce the effect of parasitic transistors in these structures also.

According to the invention there is provided a transistor having a substrate; source, gate, body and drain regions; a plurality of semiconductor zones extending laterally across the substrate, the zones being separated by separation regions; the zones including at least the source and body regions of the transistor, the source and body regions being of opposite conductivity type and forming the emitter and base of a parasitic bipolar transistor; wherein the zones include laterally wide zones and laterally narrow zones, the wide zone or zones having a lower breakdown voltage than the narrow zone or zones; and the wide and narrow zones are configured such that current passing through the wide zone or zones has a lesser susceptibility to turn on the parasitic bipolar transistor than current passing through the narrow zone or zones.

Wide zones generally have a lower breakdown voltage than narrow zones. Thus, breakdown will tend to occur first in the wide zones and so the bulk of the avalanche current will tend to flow in the wide zones which have less susceptibility to parasitic turn on. Thus, the risk of triggering the parasitic bipolar is reduced. This increases the ruggedness of the device.

In embodiments, the narrow zones include source and body regions and the wide zones include a body region but not a source region. Thus, the wide zones simply do not include the parasitic bipolar transistor formed of source, body and drain regions.

Alternatively, the wide zones may include source and body regions, but arranged to be less susceptible to triggering the parasitic bipolar transistor than the narrow zones. For example, additional measures may be taken in the wide zone such as including an autoaligned deep p-type implant (ADP) in the wide zone. Such implants may be difficult or impossible to achieve in very narrow zones, so by providing the implant in a wide zone the benefits of the implant may be achieved in structures with a zone or cell size that at first sight would appear to be too small.

The invention may be applied to vertical trench-gated devices, or devices with lateral gates. In the either case, RESURF structures may be provided to deplete part of the drain region during turn off of the FET. The invention is not restricted to FETs, but may also be applied, for example, to insulated gate bipolar transistors; in this context the source, body and drain regions are more usually termed emitter, base and collector regions.

Accordingly, in this specification the terms “source”, “body” and “drain” include the emitter, base and collector respectively of gated bipolar devices.

The zones may form a plurality of stripes across the substrate, every Nth stripe being a wide zone and the other zones being a narrow zone, where N is an integer and N≧2.

The narrow zones may include alternating source and body regions along the length of the stripe at the surface of the stripe.

In alternative embodiments, the zones may be cells, for example hexagonal or square in shape. The large cells may be wider than the narrow cells but of the same length, or alternatively both wider and longer.

In embodiments, a wide zone may be provided at the periphery of the active area, leaving the interior for one or more narrow zones.

Preferably, the drain-source breakdown voltage of the wide zone is between 1% and 15% below the drain-source breakdown voltage of the narrow zone. This is to avoid reducing the breakdown voltage excessively. The exact breakdown voltage may depend on the design voltage of the device, so for a 600V transistor the drain-source breakdown voltage of the wide zone may preferably be between 1% and 2% below the drain-source breakdown voltage of the narrow zone, whereas for a 30V transistor the drain-source breakdown voltage of the wide zone may preferably be between 7% and 10% below the drain-source breakdown voltage of the narrow zone. These figures correspond to a breakdown voltage of the wide zone of 3V to 12V less than the breakdown voltage of the narrow zone.

Embodiments of the invention, will now be described, purely by way of example, with reference to the accompanying drawings in which:

FIG. 1 illustrates a trench FET;

FIG. 2 illustrates a first embodiment of a transistor according to the invention;

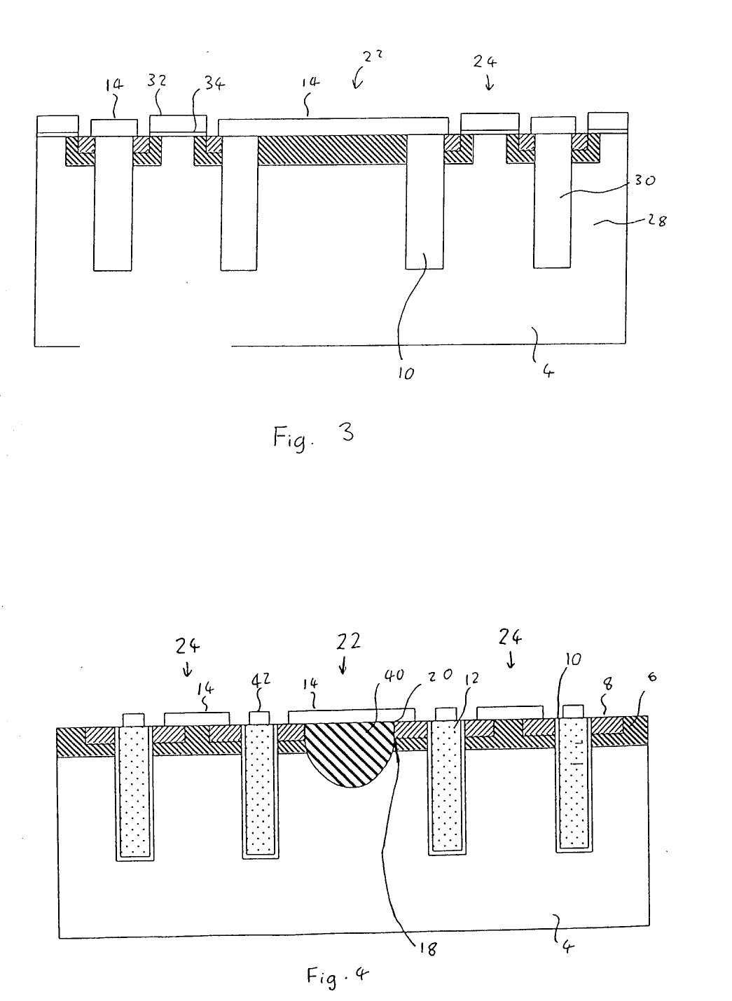

FIG. 3 illustrates a second embodiment of a transistor according to the invention; and

FIG. 4 illustrates a third embodiment of a transistor according to the invention.

Like or corresponding components are given like reference numbers in the different Figures.

Referring to FIG. 2, an n-type epilayer 4 on substrate 2 supports a plurality of wide semiconductor zones 22 and narrow semiconductor zones 24 extending in stripes across the substrate 2. The zones are separated by trenches 10 containing gates 12 separated from the semiconductor zones 22,24 by thin insulating layers 26.

The wide zones 22 contain a p-type body 6. The narrow zones 24 include a p-type body 6 and n-type source regions 8 over the body 6. The source regions are provided at intervals along the length of the stripe at the upper surface of the stripe. At regions along the length of the narrow zone stripe where source region 8 is absent, the body region 6 is exposed. A source contact contacts the source and body, a gate contact contacts the gate and a drain contact contacts the epilayer 4. For clarity, these contacts are not shown.

In normal operation, away from breakdown, the device works as a conventional trench-gated FET.

The breakdown voltage in the wide zones 22 is less than that in the narrow zones. The reason for this is that the neighbouring zones have more effect in the narrow zones 24 than in the wide zones 22 in flattening the curved electric field present when a voltage is applied between source 8 and drain 4. The breakdown voltage in the narrow cells 24 accordingly approaches closer to the theoretical (one dimensional) limit of breakdown voltage.

Thus, should breakdown occur, the bulk of the avalanche breakdown current will pass through the wide zones 22 in preference to the narrow zones 24.

Since the parasitic bipolar transistors formed of source 8, body 6 and drain 4 is only present in the narrow zones 24, the avalanche current flowing predominantly through the wide zones 22 is largely kept away from the parasitic bipolar transistors thereby reducing the chance of turning on the parasitic bipolar transistor. This increases the level of ruggedness.

In order not to reduce the breakdown voltage excessively it is desirable to target the breakdown voltage of the wide zones 22 to be just below that of the narrow zones 24.

In normal operation with the device turned on current does not flow in the wide zones 22. Thus, the number of wide 22 and narrow 24 zones needs to be adjusted for the intended use of the device. In particular, every Nth stripe may be a wide zone 22, where N is an integer and N is at least 2.

Alternatively, for small devices or those with a low ruggedness requirement, the wide zone may be provided around the periphery of the active area, for example integrally formed with the edge termination. This minimises the effect of the wide zone on the active area.

A further embodiment of the invention, applied to a RESURF type structure, is illustrated with respect to FIG. 3. The example is an MVMOS structure. Ruggedness is an important parameter of such structures and the greater ruggedness of DMOS has hitherto limited the application of MVMOS structures.

In this embodiment, RESURF diffusions 30 extend through the source 8 and body 6 regions into the drain epilayer 4, defining drift regions 28 between the trenches at the upper surface of the drain 4. The RESURF diffusions 30 are filled with p-type doped semiconductor.

The RESURF diffusions 30 define wide 22 and narrow 24 zones. A body region 6 is defined at the upper face of the wide zones 22. In the narrow zones, source 8 and body 6 regions are provided. A lateral gate 32 extends over the body 6 region at the upper surface of the narrow zones, insulated from the body by gate insulator 34.

The n doping concentration in the drift region 28 and the p doping concentration in the RESURF diffusion 30 together with the size and spacing of the regions 28,30 is arranged such that when the device is turned off the drift region 28 and RESURF diffusions 30 are fully depleted, at least in the narrow zones 24.

In use, as in the embodiment of FIG. 2, the normal operation of the device is conventional. The breakdown voltage of the wide zones 22 will again be less than that of the narrow zones 24, so should breakdown occur the avalanche current will flow preferentially in the wide zones 22. Since there is no source 8 in these regions and hence no parasitic bipolar transistor, the parasitic bipolar transistor in the narrow zones 24 will tend not to be turned on. The ruggedness of the device is thus improved.

As in the embodiment of FIG. 2, the wider spacing should be sufficient to give a low enough breakdown voltage to take avalanche current without reducing the breakdown voltage excessively.

It will accordingly be appreciated that the invention is not limited to the specific examples shown. The invention may be applied to DMOS structures, for example by replacing the trench RESURF regions 30 in FIG. 3 by body regions.

FIG. 4 illustrates an alternative structure based on a modification of the trench-gated structure of FIG. 1. There is provided a source region 8, drain region 4 and body region 6, together with gate 12 in trench 10. The source region 8 and body region 6 are both contacted by source contact 14 and gate contact 42 connects to the gate. A deep p-type implant 40 of higher doping concentration than the p-type body 6 is included in the wide zone. Should breakdown occur and a high current flow in the wide zone 22, the deep p-type implant acts as a good conductor preventing the voltage dropped between the metallisation/body boundary 20 and the source/body boundary 18 from exceeding the threshold voltage of the parasitic bipolar transistor formed by source 8, body 6 and drain 4. The propensity for this parasitic bipolar transistor to be turned on is accordingly reduced, and the ruggedness correspondingly increased. It should be noted that this is possible even if the narrow zones 24 are too narrow to include implant 40.

The invention may also be applied to trench gate devices of the type where the gates deplete a drift region. An example of this type of device is WO01/08226.

Indeed, the invention is applicable to any type of device having a number of zones or cells, wherein some of the zones can be arranged to be wider than other zones so that breakdown occurs preferentially in the wider zones. The wide zones may be wider than the narrow zones in a single lateral dimension, or cells of greater area than narrow cells.

In alternative embodiments, the invention can be applied to devices of the type described in WO01/59846, to Philips, incorporated herein by reference in its entirety, in which a plurality of semiconductor zones are separated by trenches including resistive paths of semi-insulating material. Wide zones may be provided periodically across the structure, the structure of the wide zones being adapted to avoid turning on a parasitic bipolar transistor.

The invention is also applicable to bipolar structures, such as insulated gate bipolar transistors.

Although the examples use particular doping types for the various regions it will be appreciated by the skilled person that these may be varied according to need. For example, regions described as p-type may be doped n-type, and vice versa, or alternatively just some of the doping types may be changed.

Other modifications may be made to the examples. For example, the insulated gates may be replaced by doped semiconductor gates as in the case of a junction field effect transistor (JFET).

The substrate may be of any suitable type, for example insulating, as in the case of a silicon on insulator structure, semi-insulating, or doped to be conducting.

It should be noted that for conciseness singular terms are used in the present disclosure but are intended to include the plural. Thus, although the disclosure may refer to “a gate”, “a source”, “a transistor” and the like the skilled person will realise that many devices and/or components may be included on a substrate and/or in a package and that the invention includes such multiple devices.

From reading the present disclosure, other variations and modifications will be apparent to persons skilled in the art. Such variations and modifications may involve equivalent and other features which are already known in the design, manufacture and use of semiconductor devices and which may be used in addition to or instead of features described herein. Although claims have been formulated in this application to particular combinations of features, it should be understood that the scope of disclosure also includes any novel feature or any novel combination of features disclosed herein either explicitly or implicitly or any generalisation thereof, whether or not it mitigates any or all of the same technical problems as does the present invention. The applicants hereby give notice that new claims may be formulated to any such features and/or combinations of such features during the prosecution of the present application or of any further applications derived therefrom.

1. A transistor, including a substrate; source, gate, body and drain regions; a plurality of semiconductor zones extending laterally across the substrate, the zones being separated by separation regions; the zones including at least the source and body regions of the transistor, the source and body regions being of opposite conductivity type and forming the emitter and base of a parasitic bipolar transistor, wherein the zones include laterally wide zones and laterally narrow zones, the wide zone or zones having a lower breakdown voltage than the narrow zone or zones; and the wide and narrow zones are configured such that current passing through the wide zone or zones has a lesser susceptibility to turn on the parasitic bipolar transistor than current passing through the narrow zone or zones.

2. A transistor according to claim 1 wherein the narrow zone or zones include a FET source region and body region and the wide zone or zones include a body region but not a source region so that the parasitic bipolar transistor is not present in the wide zone or zones.

3. A transistor according to claim 1 including in the wide zone or zones an implant region of the same conductivity type as the body region and higher doping than the body region, the implant region extending adjacent to the source region for rendering the parasitic bipolar transistor less susceptible to turn on.

4. A transistor according to any preceding claim wherein the separation regions are vertical insulated gates formed in trenches.

5. A transistor according to claim 1, 2 or 3 wherein the gates are lateral gates which overlie part of the source and body regions.

6. A transistor according to any preceding claim wherein the separation regions include RESURF regions for depleting at least part of the narrow zones when the transistor is switched off.

7. A transistor according to any preceding claim wherein the zones form a plurality of stripes, each stripe extending longitudinally across the substrate, every Nth stripe being a wide zone and the other zones being narrow zones, where N is an integer and N>=2.

8. A transistor according to claim 7 wherein the narrow zones include alternating source and body regions along the length of the stripe at the surface of the stripe.

9. A transistor according to any preceding claim wherein the narrow zones are semiconductor zones of alternating n and p type and the wide zones are wider semiconductor zones sandwiched between narrow zones of opposite conductivity type.

10. A transistor according to any preceding claim including a wide zone at the periphery.

11. A transistor according to any preceding claim wherein the drain-source breakdown voltage of the wide zone is between 1% and 20% less than the drain-source breakdown voltage in the narrow zone.

12. A method of operation of a transistor including a plurality of wide and narrow zones extending between source and drain contacts, gates and further including parasitic bipolar transistors arranged to be more susceptible to avalanche current flowing in the narrow zones than the wide zones,
the method including:
under conditions when a large voltage is applied between source and drain contacts, allowing avalanche breakdown to occur preferentially in the wide zones;
whereby the avalanche current flows preferentially in the wide zones where it is not susceptible to turning on the parasitic bipolar transistors.
